(19) United States
(12) Patent Application Publication
(10) Pub. No.: US 2025/0256506 A1
(43) Pub. Date: Aug. 14, 2025

(54) SEMICONDUCTOR DEVICE AND LIQUID EJECTION HEAD SUBSTRATE

(71) Applicant: CANON KABUSHIKI KAISHA, Tokyo (JP)

(72) Inventors: YUHEI HARADA, Kanagawa (JP); TOSHIO NEGISHI, Kanagawa (JP)

(21) Appl. No.: 19/043,616

(22) Filed: Feb. 3, 2025

(30) Foreign Application Priority Data
Feb. 13, 2024 (JP) 2024-019561

(51) Int. Cl. B41J 2/14; G11C 17/16; G11C 17/18; H10B 20/25

(52) U.S. Cl. CPC B41J 2/14072; G11C 17/16; G11C 17/18; H10B 20/25; B41J 2002/14491

(57) ABSTRACT

A semiconductor device includes: a semiconductor substrate; an anti-fuse element arranged on the semiconductor substrate and connected to a first terminal with a first potential; a first transistor arranged on the semiconductor substrate and connected between the anti-fuse element and a second terminal with a second potential different from the first potential; a logic circuit connected to a gate of the first transistor; and a long-pulse detection circuit connected to the logic circuit. The long-pulse detection circuit is connected to a third terminal into which a write signal for the anti-fuse element is inputted, and drive of the first transistor is stopped based on a long-pulse detection signal outputted from the long-pulse detection circuit.

### BACKGROUND OF THE INVENTION

### Field of the Invention

The present disclosure relates to a semiconductor device and a liquid ejection head substrate.

### Description of the Related Art

In recent years, a one-time programmable (OTP) memory is used in a semiconductor device to record product-specific information such as a chip ID or a setting parameter after completion of the product. The OTP memory includes a form using a fuse element and a form using an anti-fuse element. Japanese Patent Laid-Open No. 2018-134809 (hereinafter, referred to as Literature 1) discloses a configuration in which an anti-fuse element is used as the OTP memory.

Literature 1 discloses a circuit configuration including a selection logic circuit, a DMOS transistor, and a ground in a circuit that performs writing into the anti-fuse element. Moreover, Literature 1 discloses a configuration in which the writing into the anti-fuse element is performed by causing a voltage application circuit to apply a write pulse to the DMOS transistor.

In the case where a direct current (DC) voltage is erroneously continuously applied instead of the intended write pulse, there may occur a situation in which an unintentional DC current continues to flow in the anti-fuse element. As a result, this may cause a circuit defect or a condition abnormality in the anti-fuse element.

### SUMMARY OF THE INVENTION

A semiconductor device according to one aspect of the present disclosure includes: a semiconductor substrate; an anti-fuse element arranged on the semiconductor substrate and connected to a first terminal with a first potential; a first transistor arranged on the semiconductor substrate and connected between the anti-fuse element and a second terminal with a second potential different from the first potential; a logic circuit connected to a gate of the first transistor; and a long-pulse detection circuit connected to the logic circuit, the long-pulse detection circuit is connected to a third terminal into which a write signal for the anti-fuse element is inputted, and drive of the first transistor is stopped based on a long-pulse detection signal outputted from the long-pulse detection circuit.

Further features of the present invention will become apparent from the following description of exemplary embodiments with reference to the attached drawings.

### BRIEF DESCRIPTION OF THE DRAWINGS

FIG. 1 is an outer appearance perspective view illustrating an outline of a liquid ejection apparatus;

FIG. 2 is a block diagram illustrating an example of a control configuration of the liquid ejection apparatus;

FIG. 3 is a diagram illustrating an example of a circuit configuration of a semiconductor device;

FIGS. 4A and 4B illustrate examples of a timing chart;

FIG. 5 is a diagram illustrating a specific example of a cross-sectional structure;

FIGS. 6A and 6B are diagrams illustrating an example in which a long-pulse detection circuit is arranged on an inkjet print element substrate;

FIG. 7 is a diagram illustrating an example of the circuit configuration of the semiconductor device; and

FIGS. 8A and 8B illustrate examples of the timing chart.

### DESCRIPTION OF THE EMBODIMENTS

Preferable embodiments of the present disclosure are explained below in detail with reference to the attached drawings. Note that the following embodiments do not limit the matters of the present disclosure, and not all of combinations of characteristics explained in the present embodiments are necessarily essential for solving means of the present disclosure. Note that the same constituent elements are denoted by the same reference numerals.

### <Outline of Liquid Ejection Apparatus>

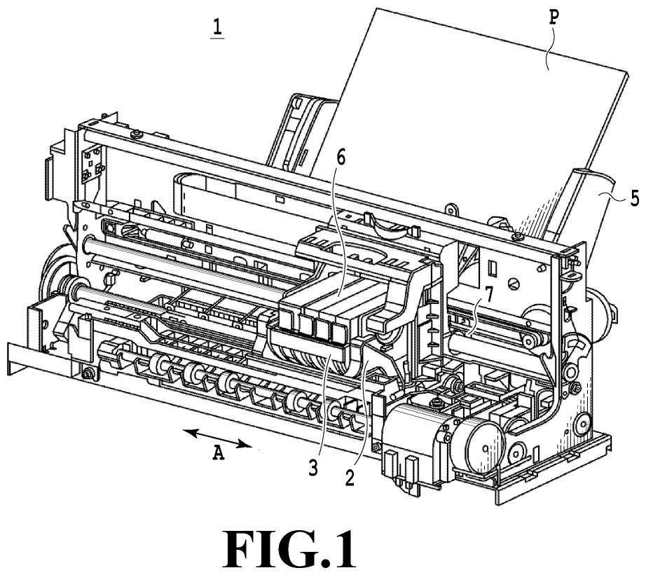

FIG. 1 is an outer appearance perspective view illustrating an outline of a liquid ejection apparatus that is an example of the present embodiment. The liquid ejection apparatus 1 includes a liquid ejection head 3 configured to eject liquid according to an inkjet method. The liquid ejection head 3 is provided with a liquid ejection head substrate including a semiconductor device to be described later. The liquid ejection apparatus 1 illustrated in FIG. 1 is an inkjet printing apparatus.

As illustrated in FIG. 1, in the liquid ejection apparatus 1, the liquid ejection head 3 configured to perform printing by ejecting liquid (inks) is mounted in a carriage 2. The liquid ejection apparatus 1 performs printing by causing the carriage 2 to reciprocally move in an arrow A direction. A print medium P such as print paper is fed via a sheet feeding mechanism 5. The sheet feeding mechanism 5 is used to convey the print medium P to a print position, and printing is performed by ejecting the inks from the liquid ejection head 3 to the print medium P at this print position.

Ink tanks 6 configured to store the inks to be supplied to the liquid ejection head 3 are attached to the carriage 2 of the liquid ejection apparatus 1, in addition to the liquid ejection head 3. The ink tanks 6 are configured to be freely attached to and detached from the carriage 2.

The liquid ejection apparatus 1 illustrated in FIG. 1 can perform color printing. Specifically, four ink cartridges storing magenta (M), cyan (C), yellow (Y), and black (K) inks, respectively, are mounted in the carriage 2 of the liquid ejection apparatus 1. These four ink cartridges are each configured to be capable of being independently attached and detached.

The liquid ejection head 3 of the present embodiment adopts an inkjet method in which the inks are ejected by using thermal energy. Accordingly, the liquid ejection head 3 includes print elements (heaters). The print elements are provided to correspond to ejection ports, respectively, and a pulse voltage is applied to each of the print elements in response to a print signal to eject the ink from the corresponding ejection port. Note that, although the thermal method in which the liquid is ejected by generating air bubbles with the print elements is adopted in the liquid ejection head of the present embodiment, any of a piezoelectric method and various other liquid ejection methods may be adopted. Moreover, although the inks are explained as an example of the liquid in the present embodiment, the liquid used in the present embodiment is not limited to the inks.

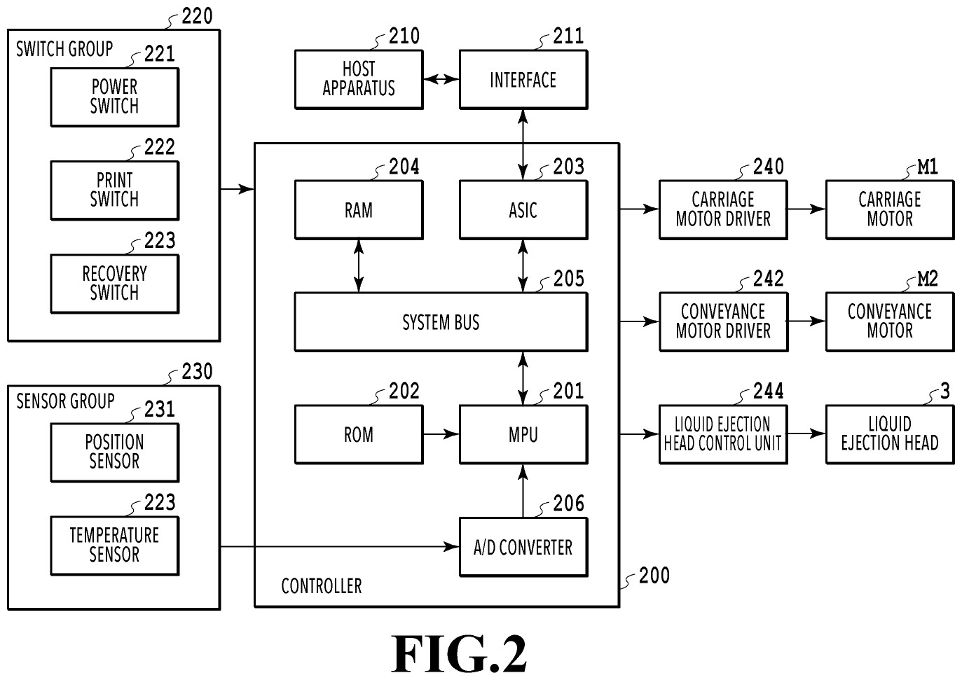

FIG. 2 is a block diagram illustrating an example of a control configuration of the liquid ejection apparatus 1 illustrated in FIG. 1. As illustrated in FIG. 2, the liquid ejection apparatus 1 includes a controller 200, a switch group 220, and a sensor group 230. The controller 200 includes a MPU 201, a ROM 202, an application specific integrated circuit (ASIC) 203, a RAM 204, a system bus 205, and an A/D converter 206.

The ROM 202 stores a program corresponding to a control sequence, a required table, and other pieces of fixed data. The ASIC 203 performs control of a carriage motor M1 and control of a conveyance motor M2, and generates a control signal for control of the liquid ejection head 3. The RAM 204 is used as a rendering area of image data, a work area for execution of a program, and the like. The system bus 205 performs exchange of data by connecting the MPU 201, the ASIC 203, and the RAM 204 to one another. The A/D converter 206 receives analog signals from the sensor group to be explained below, performs A/D conversion (analog-to-digital conversion) of the analog signals, and supplies digital signals to the MPU 201.

A host apparatus 210 is an apparatus that is a supply source of the image data. The host apparatus 210 may be mounted in the liquid ejection apparatus 1, or may be an external apparatus. The image data, commands, statuses, and the like are exchanged between the host apparatus 210 and the liquid ejection apparatus 1 via an interface (I/F) 211 by means of packet communication. Note that the liquid ejection apparatus 1 may further include an USB interface as the interface 211, in addition to a network interface. Moreover, the configuration may be such that the controller 200 can receive bit data and raster data serially transferred from the host apparatus 210 via the UBS interface.

The switch group 220 includes a power switch 221, a print switch 222, a recovery switch 223, and the like. The sensor group 230 is a sensor group for detecting an apparatus state, and includes a position sensor 231, a temperature sensor 232, and the like. In addition, photo sensors configured to detect ink remaining amounts may be provided. A carriage motor driver 240 is a driver configured drive the carriage motor M1 for reciprocate scanning of the carriage 2 in the arrow A direction in FIG. 1. A conveyance motor driver 242 is a driver configured to drive the conveyance motor M2 for conveyance of the print medium P. A liquid ejection head control unit 244 controls the liquid ejection head 3 based on an instruction of the controller 200.

The ASIC 203 transfers data for driving the print elements (heaters for ink ejection) or memory elements (anti-fuses or the like) to the liquid ejection head while directly accessing a storage area of the RAM 204, in scan for printing by the liquid ejection head 3.

Note that, although not illustrated in FIG. 2, the liquid ejection apparatus 1 includes a display unit formed of an LCD or a LED, as a user interface. The configurations illustrated in FIG. 2 and explained above are merely examples, and the liquid ejection apparatus 1 may not include some of these configurations, or may include configurations other than those illustrated in FIG. 2.

### <Circuit Configuration of Semiconductor Device>

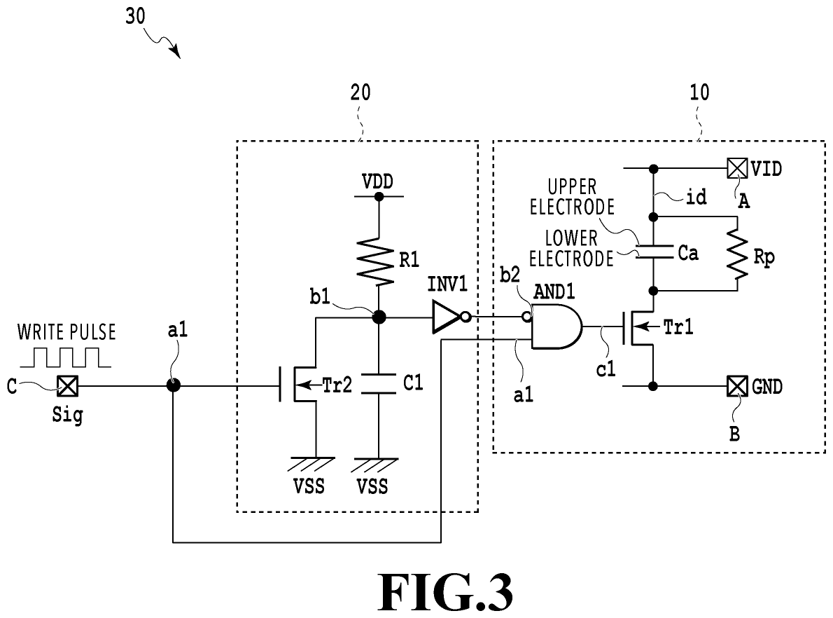

FIG. 3 is a diagram illustrating an example of a circuit configuration of a semiconductor device 30. The semiconductor device 30 of the present embodiment is included in the liquid ejection head substrate included in the liquid ejection head 3.

The semiconductor device 30 of the present embodiment includes a memory unit 10 including an anti-fuse element Ca, a transistor Tr1, and a parallel resistance Rp and a long-pulse detection circuit 20 including a transistor Tr2, a pull-up resistor R1, and a capacitance C1. The anti-fuse element Ca is an element that has a first resistance value before writing of information and that has a second resistance value smaller than the first resistance value after the writing of information, and is an element in which the resistance value of the anti-fuse element Ca changes depending on a writing operation of information. The first resistance value is preferably large. The first resistance value may be ideally infante. Moreover, a difference between the first resistance value and the second resistance value is preferably large. For example, the anti-fuse element Ca functions as a capacitive element before the writing of information, and functions as a resistance element after the wiring of information. Since FIG. 3 illustrates a state before the writing of information into the anti-fuse element Ca, the anti-fuse element Ca is expressed with a schematic symbol of capacitive element.

Such a configuration can hold information written into the anti-fuse element Ca based on a change in the resistance value of the anti-fuse element Ca. The information written into the anti-fuse element Ca is product-specific information such as, for example, a chip ID or a setting parameter, and this information is written by using an inspection device or the like in a factory in shipping of the product. Alternatively, the form may be such that a writing device is mounted in the product main body, and the user writes the information after start of use of the product.

The anti-fuse element Ca includes an upper electrode and a lower electrode. The lower electrode of the anti-fuse element Ca is connected to a second terminal B via the transistor Tr1. For example, an anti-fuse element with a metal oxide semiconductor structure (MOS structure) can be used as the anti-fuse element Ca. The upper electrode of the anti-fuse element Ca is connected to a first terminal A.

The first terminal A and the second terminal B are connection parts for electrically connecting the memory unit 10 and an external circuit to each other, and are terminals for applying a voltage to the anti-fuse element Ca or for measuring a voltage of the anti-fuse element Ca. For example, the potential of the first terminal A can be set to a high voltage (for example, 32 V) in the writing of information. A drain of the transistor Tr1 is connected to one terminal (lower electrode) of the anti-fuse element Ca, and a source of the transistor Tr1 is connected to GND. The other terminal (upper electrode) of the anti-fuse element Ca is connected to the first terminal A. The second terminal B is set to, for example, a ground potential (GND).

Note that, in the case where the high voltage applied to the first terminal A is higher than an anti-fuse element writing voltage, the memory unit 10 may include a buck circuit that steps down a VID voltage (for example, 32 V) to the writing voltage (for example, 24 V).

An operation in the writing of information into the anti-fuse element Ca is explained in FIG. 3. Applying the VID voltage (for example, 32 V) causes the high voltage (for example, 32 V) to be applied also to wiring id. In the writing of the information into the anti-fuse element Ca, a high-level signal (for example, 5.3 V) is inputted into a control signal c1 corresponding to the anti-fuse element Ca into which the information is desired to be written, and the transistor Tr1 is thereby set to an on state. The high voltage (for example, 32 V) applied to the wiring id is thereby applied to a gate insulating film of the anti-fuse element Ca. Repeating an on-off operation of this transistor Tr1 causes dielectric breakdown of the gate insulating film of the anti-fuse element Ca, and the resistance value of the anti-fuse element Ca greatly decreases. Accordingly, the anti-fuse element Ca is the capacitive element before the writing, while the anti-fuse element Ca is the resistance element after the writing.

Note that, in reading of whether the anti-fuse element Ca is in a written state or not, determination can be performed by detecting a voltage of a VID terminal electrically connected to the first terminal A, from the outside of the semiconductor device. A method of reading the information written in the anti-fuse element Ca includes a method of measuring a change in the impedance of the anti-fuse element Ca and the like.

The transistor Tr1 is an N-type high-voltage-tolerant transistor, and controls application of voltage to the anti-fuse element Ca. For example, the transistor Tr1 may be an NMOS transistor. In this case, the high-voltage-tolerant transistor is a transistor with a higher voltage tolerance than a low-voltage-tolerant transistor (Tr2 and the like) used in a logic circuit. The high-voltage-tolerant transistor is preferably formed not to fail even in a case where a voltage (for example, 32V) so high that a transistor in a general logic circuit such as a control unit cannot tolerate is applied.

In FIG. 3, the transistor Tr2 is a high-speed-drive N-type transistor for a logic circuit. A gate of the transistor Tr2 is connected to a third terminal C, and a drain of the transistor Tr2 is connected to the pull-up resistor R1 and the capacitance C1, and is configured such that a signal is inputted into an inverter INV1. A source of the transistor Tr2 is connected to a logic ground VSS (ground electrode for a signal line). In the pull-up resistor R1, a terminal on the opposite side to a terminal connected to the drain of the transistor Tr2 is connected to a logic power supply voltage VDD. In the capacitance C1, a terminal on the opposite side to a terminal connected to the drain of the transistor Tr2 is connected to the logic ground VSS.

In the present embodiment, the configuration is such that, in the case where an abnormal signal (for example, unintentional long pulse signal) is inputted from the third terminal C, the long-pulse detection circuit 20 configured as described above is used to stop the writing operation to the anti-fuse element Ca. Specific explanation is given below.

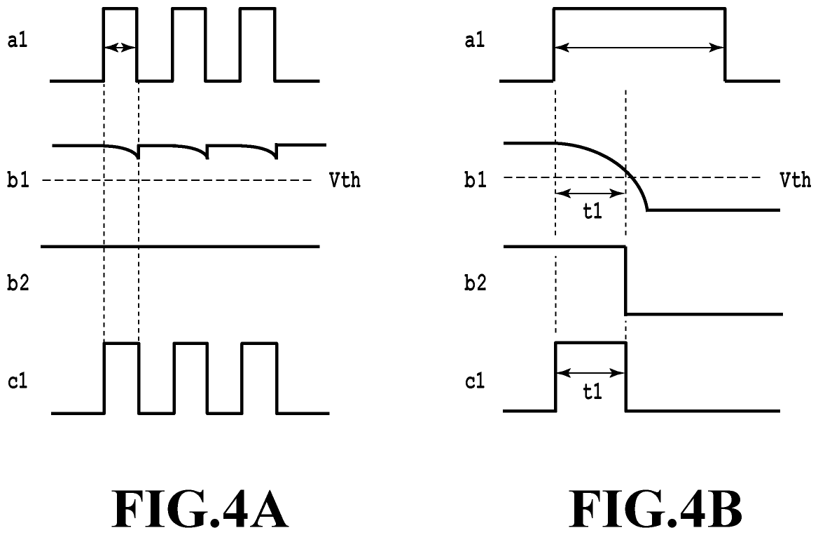

FIGS. 4A and 4B illustrate examples of a timing chart of the circuit of FIG. 3. The timing chart of the semiconductor device 30 is explained below with reference to FIGS. 3, 4A, and 4B. In FIGS. 4A and 4B, the following potentials are illustrated.

A potential a1 is a potential of the third terminal C that is an external signal input portion, and is a potential connected to a first input of a selection logic circuit AND1. A potential b1 is a potential inputted into the inverter INV1. A potential b2 is a potential connected from an output of the inverter INV1 to a second input of the selection logic circuit AND1. A potential c1 is a potential of an output of the selection logic circuit AND1, and is a potential inputted into a gate of the transistor Tr1. The selection logic circuit AND1 is a logical AND circuit for selecting an anti-fuse element to be driven.

FIG. 4A illustrates a state where a write pulse signal that is a normal write signal is inputted from the third terminal C. Meanwhile, FIG. 4B illustrates a state where an abnormal signal (for example, unintentional long-pulse signal) is inputted from the third terminal C. The normal write pulse signal refers to a pulse signal and a square wave signal configured to have, for example, a duty of 50%, a cycle of 5 MHz, and the like. The abnormal signal refers to a long-pulse signal having a long period DC component (for example, 100 us or more), and is assumed to correspond to a case where an unexpected failure occurs on the external input side and an unintentional long-pulse signal is inputted.

In FIG. 3, the long-pulse detection circuit 20 uses the pull-up resistor R1. The pull-up resistor is a resistance used to maintain a state where a voltage inputted into an input terminal (inverter INV1 in the present example) is high in the case where a switch (transistor Tr2 in the present example) is in an off state. Accordingly, in the state where the transistor Tr2 is off, the capacitance C1 is charged by an electric charge from the logic power supply voltage VDD, and a high signal (for example, 3.3 V) supplied by the logic power supply voltage VDD is inputted into the inverter INV1.

In the case where the transistor Tr2 switches from the off state to the on state, the electric charge charging the capacitance C1 is discharged to the logic ground VSS via the transistor Tr2. This discharging is not completed instantaneously, and a discharge time is defined by a RC time constant (=τ) determined by the pull-up resistor R1 and the capacitance C1.

First, an example in which the normal write pulse signal is inputted is explained. In the case where the normal write pulse signal is inputted from the third terminal C as in FIG. 4A, in the potential b1 inputted into the inverter INV1, the transistor Tr2 switches to the on state, and the discharging of the capacitance C1 is performed. However, since the transistor Tr2 switches to the off state again before completion of the discharging of the capacitance C1, the capacitance C1 is charged by the electric charge again. Accordingly, the potential b1 inputted into the inverter INV1 does not fall below a threshold voltage Vth at which the output of the inverter INV1 is switched, and the output potential b2 of the inverter INV1 is maintained at a high output. The output c1 of the selection logic circuit AND1 in a stage before the transistor Tr1 configured to drive the anti-fuse element Ca is a logical AND output of the input potential a1 and the input potential b2. Accordingly, since the output potential b2 is maintained at the high output, a write pulse waveform same as the input potential a1 is outputted, and as a result, the wiring operation to the anti-fuse element Ca can be performed.

Note that the inverter INV1 and the selection logic circuit AND1 may include a booster circuit that steps up the logic power supply voltage VDD (for example, 3.3V) to a voltage (for example, 5.2 V) necessary for the gate of the transistor Tr1 configured to drive the anti-fuse element.

Next, an example in which the abnormal signal is inputted is explained. In the case where the long-pulse abnormal signal is inputted from the third terminal C as in FIG. 4B, in the potential b1 inputted into the inverter INV1, the transistor Tr2 switches to the on state, and the discharging of the capacitance C1 progresses. Then, in the case where a time period t1 determined by the time constant t elapses, the potential b1 inputted into the inverter INV1 falls below the threshold voltage Vth at which the output of the inverter INV1 is switched. From this point on, the output potential b2 of the inverter INV1 becomes a low output (for example, ground potential). Since the potential b2 is the high output until the time period t1 elapses, the output potential c1 of the selection logic circuit AND1 is outputted in the same waveform as a1. Meanwhile, after the elapse of the time period t1, the potential b2 becomes a low output, and c1 also becomes a low output. Accordingly, the transistor Tr1 configured to drive the anti-fuse element Ca is not continuously set to the on state even in the case where the abnormal signal (long-pulse DC signal) is inputted in the potential a1. Accordingly, it is possible to suppress flow of an unintentional DC current to the anti-fuse element Ca. As a result, a defect of the anti-fuse element Ca and a circuit failure can be suppressed. As described above, the output potential b2 of the inverter INV1 corresponds to a long-pulse detection signal outputted from the long-pulse detection circuit 20.

As an example, in the case where the pull-up resistor R1 is 550 kΩ and the capacitance C1 is 8 pF, the time constant τ is 4.4 usec, and a time taken to invert the output of the inverter INV1 is about 2 μsec. An inputted write pulse by the DC current from this point on is disabled, and no current flows to the anti-fuse element and the circuit.

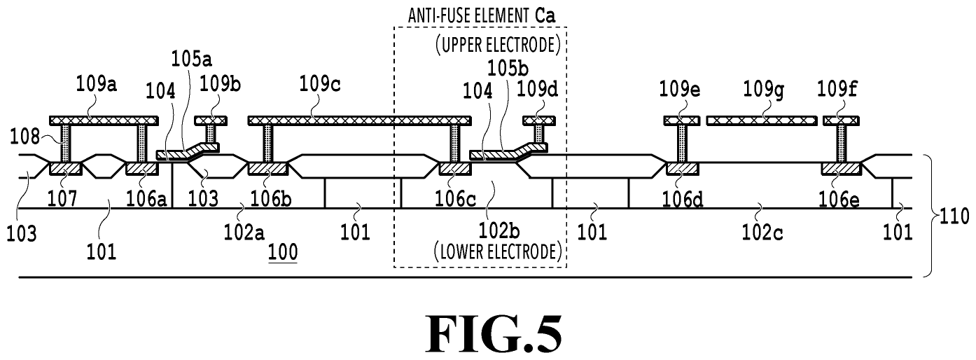

FIG. 5 is a diagram illustrating a specific example of a cross-sectional structure of the anti-fuse element Ca, the parallel resistance Rp, and the transistor Tr1 illustrated in FIG. 3. A specific example of the cross-sectional structure is explained by using FIG. 5.

In a semiconductor substrate 110, a P-well region 101 and N-well regions 102a, 102b, and 102c are formed on a P-type silicon substrate 100. The P-well region 101 can be formed in the same step as that for a P-well in a NMOS transistor forming a logic circuit. Moreover, the N-well regions 102a, 102b, and 102c can be formed in the same step as that for an N-well in a PMOS transistor forming the logic circuit.

Note that an impurity concentration of the N-well regions with respect to the P-type silicon substrate 100 is a concentration at which a breakdown voltage of the N-well regions 102a, 102b, and 102c and the P-type silicon substrate 100 is higher than the voltage of the VID terminal in the case of high voltage. Moreover, impurity concentrations of the P-well region 101 and the N-well regions 102a, 102b, and 102c are concentrations at which a breakdown voltage of the P-well region 101 and the N-well regions 102a and 102b is higher than the voltage of the VID terminal in the case of high voltage.

A field oxide film 103, high-concentration N-type diffusion regions 106a to 106e, and a high-concentration P-type diffusion region 107 are formed on the P-well region 101 and the N-well regions 102a, 102b, and 102c. The field oxide film 103 can be formed by, for example, a local oxidation of silicon (LOCOS) method.

A configuration of the transistor Tr1 that is a high-voltage-tolerant NMOS transistor is explained. A gate electrode 105a is arranged on the P-well region 101 and the N-well region 102a adjacent to each other, via a gate insulating film 104. A region where the P-well region 101 and the gate electrode 105a overlap each other is a channel formation region.

The high-concentration N-type diffusion region 106a is the source of the transistor Tr1. The high-concentration P-type diffusion region 107 is a back gate electrode of the transistor Tr1. The N-well region 102a includes a portion extending to a position below the gate electrode 105a, as an electric field grading region of the drain. The high-concentration N-type diffusion region 106b formed in the N-well region 102a is the drain electrode of the transistor Tr1.

Moreover, the drain side of the gate electrode 105a has a structure riding on the field oxide film 103 formed in the N-well region 102a, or a so-called LOCOS offset structure. This allows a gate-drain breakdown voltage to be secured even in the off-state of the transistor Tr1, that is even in the case where the voltage of the gate electrode is the GND potential and the voltage of the drain electrode increases to the voltage of the VID terminal in the case of high voltage.

Next, a structure of the anti-fuse element Ca is explained. The anti-fuse element Ca includes the upper electrode, the lower electrode, and an insulating layer between these electrodes. For example, an electrode 105b provided on the N-well region 102b via the gate insulating film 104 functions as the upper electrode of the anti-fuse element Ca. Moreover, a portion of the N-well region 102b that is connected to the high-concentration N-type diffusion region 106c and that overlaps the upper electrode in a plan view with respect to a plane on which elements such as the transistor Tr1 of the semiconductor substrate 110 are arranged functions as the lower electrode. Note that the plan view with respect to the plane on which the elements such as the transistor Tr1, the anti-fuse element Ca, and the parallel resistance Rp are arranged is, for example, a plan view with respect to a surface of the channel formation region of the transistor Tr1.

In the example of FIG. 5, the high-concentration N-type diffusion region 106c is formed only in a region of the N-well region 102b where the N-well region 102b does not overlap the upper electrode in the plan view. However, the high-concentration N-type diffusion region 106c is not limited to this. For example, the high-concentration N-type diffusion region 106c may be formed partially or entirely in the region where the N-well region 102b overlaps the upper electrode. In the case where the high-concentration N-type diffusion region 106c is formed also in the region where the N-well region 102b overlaps the upper electrode in the plan view, an overlapping portion of the high-concentration N-type diffusion region 106c also functions as the lower electrode of the anti-fuse element Ca.

Note that, although the lower electrode of the anti-fuse element Ca is connected to the drain of the transistor Tr1 in the example of FIGS. 3 and 5, the configuration may be such that the upper electrode is connected to the drain of the transistor Tr1 and the lower electrode is connected to the high voltage (first terminal A illustrated in FIG. 3).

The gate insulating film 104 can be formed in a step of forming the gate insulating film of the transistor Tr2 forming the logic circuit, and can be formed of, for example, an oxide film. Moreover, the electrodes 105a and 105b may be, for example, a polysilicon layer. The polysilicon layer, the high-concentration N-type diffusion regions 106a to 106c, and the high-concentration P-type diffusion region 107 can be formed in the same step as a step of forming the transistor Tr2 and the elements forming the low-voltage-tolerate logic circuit.

As described above, the anti-fuse element Ca is the capacitive element with the MOS structure, and the transistor that controls the writing to the anti-fuse element Ca is the MOS transistor. Accordingly, the anti-fuse element Ca and the transistor can be formed in the same step. Thus, the semiconductor device can be formed in few steps at low cost.

An insulating film provided with multiple contact portions 108 are provided on the high-concentration P-type diffusion region 107, the N-type diffusion regions 106a to 106e, and the field oxide film 103, and conductive layers 109a to 109f are provided on the insulating film. The conductive layers 109a to 109f can be made of a metal such as, for example, aluminum. Note that a manufacturing method, a material, and a structure of the conductive layers 109a to 109f, the electrodes, and wiring are not limited as long as the conductive layers 109a to 109f, the electrodes, and the wiring are electrically connected to one another.

In FIG. 5, the capacitive element in which the lower electrode and the upper electrode are formed of the N-well region and the polysilicon is illustrated as an example of the anti-fuse element Ca. However, the anti-fuse element Ca is not limited to this structure, and may be, for example, a capacitive element using a PMOS transistor. One of the lower electrode and the upper electrode of the anti-fuse element Ca functions as the one terminal, and the other functions as the other terminal.

The parallel resistance Rp is a diffusion resistance, includes the N-well region 102c that is a semiconductor region in the semiconductor substrate 110, and is connected to the conductive layers 109e and 109f via the high-concentration N-type diffusion regions 106d and 106e, respectively. The parallel resistance Rp is not limited to this structure. For example, a resistance element made of the conductive layer or a resistance element made of the polysilicon may be used as the parallel resistance Rp. The same applies also to the pull-up resistor R1. Specifically, the pull-up resistor R1 and the parallel resistance Rp (second resistance element) may be made of a common material.

The insulating film is an insulating layer formed on the semiconductor substrate 110 to cover the transistor Tr1, the parallel resistance Rp, and the like, and is made of, for example, silicon oxide. The insulating layer is not limited to silicon oxide, and may be made of silicon nitride or silicon carbide, or may be a laminate or a mixture layer of these materials.

The conductive layer 109a is connected to the source and the back gate of the transistor Tr1 via the contact portions 108, and is provided with the ground potential. The conductive layer 109b is connected to the gate electrode 105a of the transistor Tr1 via the contact portion 108. The conductive layer 109c is connected to the drain electrode of the transistor Tr1 and the lower electrode of the anti-fuse element Ca via the contact portions 108. The conductive layer 109d is connected to the upper electrode of the anti-fuse element Ca via the contact portion 108, and is connected to the first terminal A illustrated in FIG. 3 in a not-illustrated portion. The high voltage (for example, 32 V) is applied to the conductive layer 109d via the first terminal A in the writing. The conductive layer 109d is connected to the conductive layer 109c (not illustrated), and the conductive layer 109e is connected to the conductive layer 109f (not illustrated).

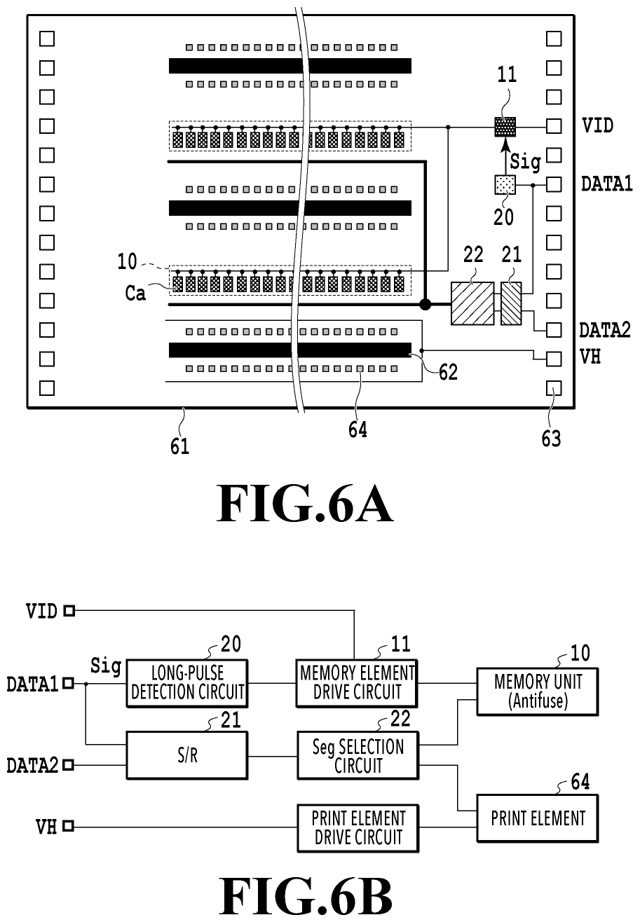

FIGS. 6A and 6B are diagrams illustrating an example in which the long-pulse detection circuit 20 of the present embodiment is arranged on an inkjet print element substrate 61. FIG. 6A is a layout diagram illustrating the example in which the long-pulse detection circuit 20 is arranged on the inkjet print element substrate 61. FIG. 6B illustrates an example of a connection block diagram of FIG. 6A.

As illustrated in FIG. 6A, the memory units 10 are arranged in parallel to a direction in which print elements 64 are aligned. Moreover, an ink supply port 62 is arranged between each two print element arrays in which the print elements 64 are aligned. Note that, although the memory units 10 illustrated in FIG. 6 correspond to the memory unit 10 in FIG. 3, to be more specific, the memory units 10 illustrated in FIG. 6 correspond to the anti-fuse element Ca and the parallel resistance Rp in FIG. 3. External connection terminals 63 include the various terminals illustrated in FIG. 3. Specifically, the external connection terminals 63 include the first terminal A for application of the VID voltage, the second terminal B corresponding to the ground potential (GND), and the third terminal C being a DATA1 terminal into which an external signal is inputted. Note that the logic ground (VSS) is not illustrated in FIG. 6. The logic ground (VSS) and the second terminal B that supplies the ground potential (GND) are separated from each other in the semiconductor device.

A memory element drive circuit 11 illustrated in FIG. 6 is a circuit for driving the anti-fuse elements Ca. Specifically, the memory element drive circuit 11 may be a configuration other than the anti-fuse element Ca and the parallel resistance Rp in FIG. 3. As an example, the memory element drive circuit 11 corresponds to the selection logic circuit AND1 and the transistor Tr1 in FIG. 3. Note that, in the case where the semiconductor device 30 includes the buck circuit as described above, the buck circuit may be included in the memory element drive circuit 11.

A Sig signal that is the write signal inputted from a DATA1 terminal is inputted into the long-pulse detection circuit 20 and a shift register (S/R) 21. Moreover, a signal from a DATA2 terminal is inputted into the S/R 21. The S/R 21 converts inputted serial data to parallel data, and outputs the parallel data. A Seg selection circuit 22 is provided to correspond to each of the memory units 10 and each of the print elements 64. The Seg selection circuits 22 receives the parallel data converted in the S/R 21, and determines whether to select a segment (Seg) or not. The memory unit 10 in Seg selected by the Seg selection circuit 22 is driven by the memory element drive circuit 11. The memory element drive circuit 11 is provided to correspond to the memory units 10. Specifically, one long-pulse detection circuit 20 is connected to multiple anti-fuse elements Ca, and can drive multiple anti-fuse elements Ca.

As illustrated in FIG. 6A, in the inkjet print element substrate 61 in the present embodiment, the shift register circuit 21, the Seg selection circuit 22, and the long-pulse detection circuit 20 are arranged in a region between an external connection terminal 63 array group and a print element 64 array group. Moreover, the long-pulse detection circuit 20 is preferably arranged as close as possible to the terminal into which the write signal is inputted (DATA1 terminal in the example of FIG. 6A) with no other circuits provided between the terminal and itself to suppress mixing of the DC current into the other circuits.

Note that the layout illustrated in FIG. 6A and the block diagram illustrated in FIG. 6B are merely examples, and the present disclosure is not limited to these examples. Although the layout illustrated in FIG. 6A illustrates an example in which the memory element drive circuit 11 and the Seg selection circuit 22 are gathered at a position away from the memory units 10 and the print elements 64, the present disclosure is not limited to this form. Moreover, the position of the long-pulse detection circuit 20 is not limited to the position illustrated in FIG. 6A, and it is only necessary that the long-pulse detection circuit 20 is provided in a stage before the circuit configured to drive the anti-fuse element Ca.

Note that the form explained above is explanation of the circuit that writes information into the anti-fuse element Ca. The long-pulse detection circuit 20 may be configured not to be driven in the case where the information of the anti-fuse element Ca is read.

As explained above, in the present embodiment, the long-pulse detection circuit is provided in the circuit configured to write information into the anti-fuse element Ca. Then, in the case where the long-pulse detection circuit detects an abnormal signal (for example, long-pulse DC voltage), the circuit is configured to stop the writing operation to the anti-fuse element. Thus, according to the present embodiment, it is possible to suppress the case where an unintentional DC current flows to the anti-fuse element. Accordingly, it is possible to suppress occurrence of an anti-fuse element failure and a circuit defect.

### Second Embodiment

In the first embodiment, the example in which the pull-up resistor R1 is used in the long-pulse detection circuit 20 is explained. In the present embodiment, an example in which a pull-down resistor R2 is used in the long-pulse detection circuit 20 is explained. Note that, since a basic configuration is the same as that in the example explained in the first embodiment, differences are mainly explained below.

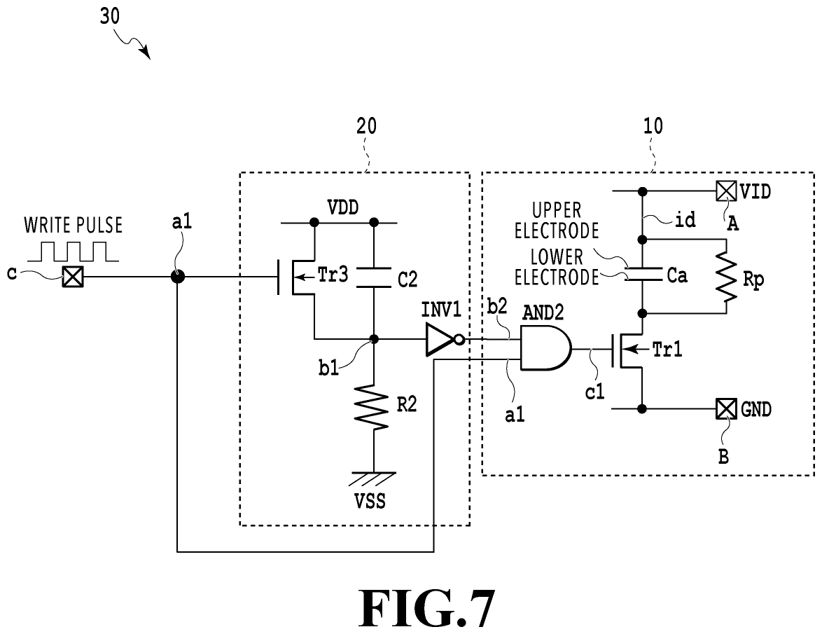

FIG. 7 is a diagram illustrating an example of a circuit configuration of the semiconductor device 30 in the present embodiment. As illustrated in FIG. 7, the pull-down resistor R2 is used in the long-pulse detection circuit 20 of the present embodiment.

In the long-pulse detection circuit 20 of FIG. 7, a transistor Tr3 is a P-type transistor. A gate of the transistor Tr3 is connected to the third terminal C. A source of the transistor Tr3 is connected to the pull-down resistor R2 and a capacitance C2, and is configured such that a signal is inputted into the inverter INV1. A drain of the transistor Tr3 is connected to the logic power supply voltage VDD. In the pull-down resistor R2, a terminal on the opposite side to a terminal connected to the source of the transistor Tr3 is connected to the logic ground VSS. In the capacitance C2, a terminal on the opposite side to the source of the transistor Tr3 is connected to the logic power supply voltage VDD.

The pull-down resistor is a resistance used to maintain a state where the voltage inputted into the input terminal (in the present example, inverter INV1) is low in the case where the switch is in the off state. Accordingly, in the state where the transistor Tr3 is off, the capacitance C2 is not charged by an electric charge from the logic power supply voltage, and a low signal (for example, 0 V) corresponding to the logic ground VSS is inputted into the inverter INV1.

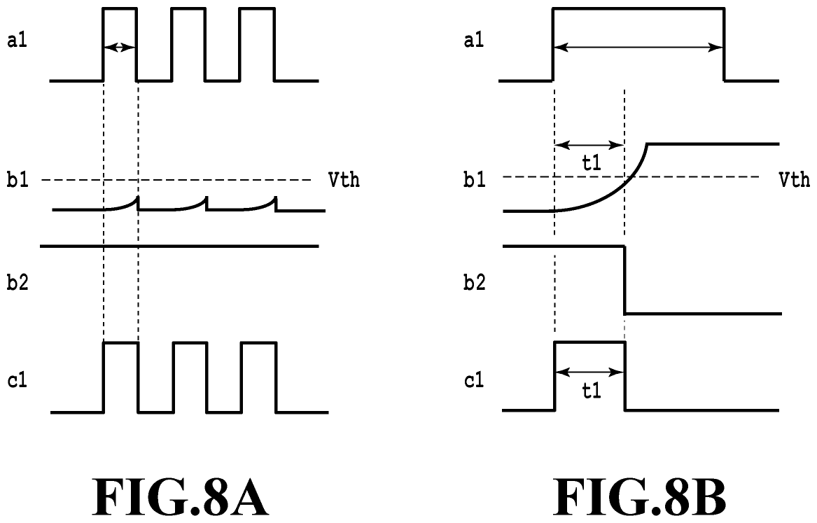

FIGS. 8A and 8B illustrate examples of a timing chart of the circuit of FIG. 7. The timing chart of the semiconductor device 30 is explained below with reference to FIGS. 7, 8A, and 8B. In FIGS. 8A and 8B, the following potentials are illustrated.

A potential a1 is a potential of the third terminal C that is an external signal input portion, and is a potential connected to a first input of a selection logic circuit AND2. A potential b1 is a potential inputted into the inverter INV1. A potential b2 is a potential connected from an output of the inverter INV1 to a second input of the selection logic circuit AND2. A potential c1 is a potential of an output of the selection logic circuit AND2, and is a potential inputted into the gate of the transistor Tr1. The selection logic circuit AND2 is a logical AND circuit for selecting an anti-fuse element to be driven.

FIG. 8A illustrates a state where a normal write pulse signal is inputted from the third terminal C. FIG. 8B illustrates a state where an abnormal signal (for example, unintentional long-pulse signal) is inputted from the third terminal C.

Compared to FIGS. 4A and 4B, in FIGS. 8A and 8B, the long-pulse detection circuit 20 has a pull-down configuration, and the change of the potential b1 is inverted from that in FIGS. 4A and 4B. Compared to FIGS. 4A and 4B, the shape of the waveform of the potential b1 in FIGS. 8A and 8B is the same as the inverted shape of FIGS. 4A and 4B. Accordingly, the same control signal as that in FIGS. 4A and 4B can be outputted as the potential c1 also in the configuration illustrated in FIG. 7 by performing logical inversion with an inverter or the like. Accordingly, as in the example explained in the first embodiment, no unintentional DC current flows in the anti-fuse element Ca after elapse of the time determined by the RC time constant (=τ). Thus, it is possible to suppress occurrence of an anti-fuse element failure and a circuit defect.

Note that, in the configuration using the pull-up resistor as in the first embodiment, there is a concern that, in the case where swing (voltage fluctuation) of the logic power supply voltage VDD occurs due to an external noise, a fluctuation of the potential b1 becomes different from an assumed fluctuation and the time in which the write pulse is enabled changes. Meanwhile, since the present embodiment has the configuration using the pull-down resistor, the fluctuation of the potential b1 is less likely to be affected by the swing of the logic power supply voltage VDD. In contrast, the fluctuation of the potential b1 is affected by swing (voltage fluctuation) of the logic ground VSS. Accordingly, it is preferable to use an advantageous embodiment depending on a condition of the device in which the semiconductor device is to be mounted.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-019561, filed Feb. 13, 2024, which is hereby incorporated by reference wherein in its entirety.

What is claimed is:

1. A semiconductor device comprising:
a semiconductor substrate;
an anti-fuse element arranged on the semiconductor substrate and connected to a first terminal with a first potential;
a first transistor arranged on the semiconductor substrate and connected between the anti-fuse element and a second terminal with a second potential different from the first potential;
a logic circuit connected to a gate of the first transistor; and
a long-pulse detection circuit connected to the logic circuit, wherein
the long-pulse detection circuit is connected to a third terminal into which a write signal for the anti-fuse element is inputted, and
drive of the first transistor is stopped based on a long-pulse detection signal outputted from the long-pulse detection circuit.

2. The semiconductor device according to claim 1, wherein the logic circuit outputs a signal to the gate of the first transistor based on the long-pulse detection signal and the write signal.

3. The semiconductor device according to claim 2, wherein the logic circuit outputs a signal of turning off the first transistor in a case where the long-pulse detection signal is a signal of detection of a long pulse.

4. The semiconductor device according to claim 1, wherein
the long-pulse detection circuit includes a resistance element, a capacitance, a second transistor, and an inverter, and
a gate of the second transistor is connected to the third terminal,
a drain of the second transistor is connected to the resistance element, the capacitance, and the inverter,
a source of the second transistor is connected to a logic ground,
in the resistance element, a terminal on an opposite side to a terminal connected to the drain of the second transistor is connected to a logic power supply,
in the capacitance, a terminal on an opposite side to a terminal connected to the drain of the second transistor is connected to the logic ground, and
the inverter is connected to the logic circuit.

5. The semiconductor device according to claim 1, wherein
the long-pulse detection circuit includes a resistance element, a capacitance, a second transistor, and an inverter,
a gate of the second transistor is connected to the third terminal,
a source of the second transistor is connected to the resistance element, the capacitance, and the inverter,
a drain of the second transistor is connected to a logic power supply,
in the resistance element, a terminal on an opposite side to a terminal connected to the source of the second transistor is connected to a logic ground,
in the capacitance, a terminal on an opposite side to a terminal connected to the source of the second transistor is connected to the logic power supply, and
the inverter is connected to the logic circuit.

6. The semiconductor device according to claim 4, wherein the first terminal and the logic power supply have potentials different from each other.

7. The semiconductor device according to claim 4, wherein the second terminal and the logic ground are separated from each other in the semiconductor device.

8. The semiconductor device according to claim 4, wherein the second transistor is a transistor used in a logic circuit, and is an N-type low-voltage-tolerant transistor.

9. The semiconductor device according to claim 1, wherein the first terminal supplies a write voltage for the anti-fuse element, and the second terminal is a ground.

10. The semiconductor device according to claim 1, wherein the first transistor is an N-type high-voltage-tolerant transistor.

11. The semiconductor device according to claim 1, further comprising a second resistance element arranged on the semiconductor substrate and connected between the first terminal and the first transistor in parallel to the anti-fuse element.

12. The semiconductor device according to claim 11, wherein the resistance element included in the long-pulse detection circuit and the second resistance element are made of a common material.

13. The semiconductor device according to claim 12, wherein the common material is a diffusion resistance.

14. The semiconductor device according to claim 1, wherein one of the long-pulse detection circuit is connected to a plurality of the anti-fuse elements.

15. A liquid ejection head substrate comprising a semiconductor device including:
a semiconductor substrate;
an anti-fuse element arranged on the semiconductor substrate and connected to a first terminal with a first potential;
a first transistor arranged on the semiconductor substrate and connected between the anti-fuse element and a second terminal with a second potential different from the first potential;
a logic circuit connected to a gate of the first transistor; and
a long-pulse detection circuit connected to the logic circuit, wherein
the long-pulse detection circuit is connected to a third terminal into which a write signal for the anti-fuse element is inputted, and
drive of the first transistor is stopped based on a long-pulse detection signal outputted from the long-pulse detection circuit.
